(19) United States
(12) Patent Application Publication
(10) Pub. No.: US 2017/0069843 A1
(43) Pub. Date: Mar. 9, 2017

(54) DEPOSITION MASK AND METHOD OF FABRICATING THE SAME

(71) Applicant: SAMSUNG DISPLAY CO., LTD., Yongin-si (KR)

(72) Inventors: Hoon KANG, Suwon-si (KR); Bum Soo KAM, Yongin-si (KR); Chong Sup CHANG, Hwaseong-si (KR); Woo Seok JEON, Seoul (KR)

(21) Appl. No.: 15/092,967

(22) Filed: Apr. 7, 2016

(30) Foreign Application Priority Data
Sep. 9, 2015 (KR) 10-2015-0127581

(51) Int. Cl. H01L 51/00; B05B 15/04

(52) U.S. Cl. CPC H01L 51/0011; B05B 15/045; H01L 51/5012

(57) ABSTRACT

A method of fabricating a deposition mask, the method including forming a photoresist pattern on a base member, the photoresist pattern having a plurality of inversely tapered photo patterns and a photo opening defined by the photo patterns; forming a mask material layer in the photo opening and on the photo patterns; removing the photo patterns and the mask material layer formed on the photo patterns, leaving the mask material layer formed in the photo opening; and removing the base member.

### CROSS-REFERENCE TO RELATED APPLICATION

Korean Patent Application No. 10-2015-0127581, filed on Sep. 9, 2015, in the Korean Intellectual Property Office, and entitled: “Deposition Mask and Method of Fabricating the Same,” is incorporated by reference herein in its entirety.

### BACKGROUND

1. Field

Embodiments relate to a deposition mask and a method of fabricating the same.

2. Description of the Related Art

Of light-emitting display devices, organic light-emitting display devices, which may be self-luminous display devices, may be next-generation display devices due to, for example, their wide viewing angle, high contrast, and fast response speed.

An organic light-emitting display device may include a middle layer, such as a light-emitting layer, between electrodes which face each other. The electrodes and the middle layer may be formed using various methods. One of the methods may be a deposition method.

### SUMMARY

Embodiments may be realized by providing a method of fabricating a deposition mask, the method including forming a photoresist pattern on a base member, the photoresist pattern having a plurality of inversely tapered photo patterns and a photo opening defined by the photo patterns; forming a mask material layer in the photo opening and on the photo patterns; removing the photo patterns and the mask material layer formed on the photo patterns, leaving the mask material layer formed in the photo opening; and removing the base member.

Each of the photo patterns may have a first surface contacting the base member and a second surface facing the first surface, each of the photo patterns may include a first photo pattern becoming narrower from the second surface toward the first surface, the first photo pattern having a curved side surface, and a second photo pattern becoming narrower from the first photo pattern toward the first surface, the second photo pattern having a curved side surface extending from the curved side surface of the first photo pattern, and an inflection point may be located at a boundary between the curved side surface of the first photo pattern and the curved side surface of the second photo pattern.

Each of the photo patterns may have a maximum width at the second surface and a minimum width at the first surface, and a difference between the maximum width and the minimum width may be 3 μm or more.

The mask material layer may have a thickness of 1 to 20 μm.

Forming the mask material layer may include depositing a metal material or an inorganic material on the base member having the photoresist pattern using a deposition method.

In forming the mask material layer, the mask material layer formed in the photo opening may be separated from the mask material layer formed on the photo patterns.

Each of the photo patterns may further include a separation groove in the curved side surface of the first photo pattern, the separation groove being located higher than the mask material layer.

The curved side surface of the first photo pattern may include a first side surface, a second side surface, a third side surface, and a fourth side surface, which are continuous from the second surface of each of the photo patterns, inflection points may be respectively located at a boundary between the first side surface and the second side surface, at a boundary between the second side surface and the third side surface, and at a boundary between the third side surface and the fourth side surface, and the separation groove may be defined by the second side surface and the third side surface.

Forming the photoresist pattern may include patterning a photoresist material layer formed on the base member, and the photoresist material layer may include a negative photoresist material, which may contain a binder, a photosensitizer, a solvent, and an additive that captures radicals generated by the photosensitizer in response to irradiation of light.

The additive may be added in an amount of 5 to 30% by weight based on 100% by weight of the photosensitizer.

Embodiments may be realized by providing a method of fabricating a deposition mask, the method including forming a photoresist pattern on a base member, the photoresist pattern having a plurality of inversely tapered photo patterns and a photo opening defined by the photo patterns; forming a mask material layer in the photo opening; removing the photo patterns, leaving the mask material layer formed in the photo opening; and removing the base member, each of the photo patterns having a first surface contacting the base member and a second surface facing the first surface, each of the photo patterns including a first photo pattern becoming narrower from the second surface toward the first surface, the first photo pattern having a curved side surface, and a second photo pattern becoming narrower from the first photo pattern toward the first surface, the second photo pattern having a curved side surface extending from the curved side surface of the first photo pattern, an inflection point being located at a boundary between the curved side surface of the first photo pattern and the curved side surface of the second photo pattern.

Each of the photo patterns may have a maximum width at the second surface and a minimum width at the first surface, and a difference between the maximum width and the minimum width may be 3 μm or more.

The base member may include a metal substrate, and forming the mask material layer may include plating a metal material on a surface of the base member using a plating method.

The mask material layer may have a thickness of 1 to 20 μm.

Forming the photoresist pattern may include patterning a photoresist material layer formed on the base member, and the photoresist material layer may include a negative photoresist material, which may contain a binder, a photosensitizer, a solvent, and an additive that captures radicals generated by the photosensitizer in response to irradiation of light.

Embodiments may be realized by providing a deposition mask, including a blocking part including an uneven first surface and an even second surface facing the first surface; and a plurality of pattern openings surrounded by the blocking part, each of the pattern openings including a first opening and a second opening connected to each other between the first surface and the second surface of the blocking part, the first opening becoming narrower from the first surface of the blocking part toward the second surface of the blocking part, the first opening having a curved side surface, and the second opening becoming narrower from the first opening toward the second surface of the blocking part, the second opening having a curved side surface extending from the curved side surface of the first opening, and an inflection point being located at a boundary between the curved side surface of the first opening and the curved side surface of the second opening.

Each of the pattern openings may have a maximum width at the first surface of the blocking part and a minimum width at the second surface of the blocking part, a difference between the maximum width and the minimum width may be 3 μm or more, and the blocking part may have a thickness of 1 to 20 μm.

The first surface of the blocking part may be a convex surface.

The blocking part may contain a metal material or an inorganic material.

A taper angle formed by a virtual plane connecting the curved side surface of the first opening located at the first surface of the blocking part and the curved side surface of the second opening located at the second surface of the blocking part and a virtual plane parallel to the first surface of the blocking part may be 45 degrees or less.

### BRIEF DESCRIPTION OF THE DRAWINGS

Features will become apparent to those of skill in the art by describing in detail exemplary embodiments with reference to the attached drawings in which:

FIG. 1 illustrates a perspective view of a deposition mask according to an embodiment which is placed on a mask frame;

FIG. 2 illustrates a plan view of the deposition mask of FIG. 1;

FIG. 3 illustrates a cross-sectional view taken along the line I-I′ of FIG. 2;

FIG. 4 illustrates the configuration of a deposition device to describe a deposition process performed using the deposition mask of FIG. 1;

FIGS. 5 and 6 illustrate cross-sectional views of deposition masks according to various embodiments;

FIGS. 7 through 11 illustrate cross-sectional views of a method of fabricating the deposition mask of FIGS. 1 through 3;

FIGS. 12 through 14 illustrate cross-sectional views of a method of fabricating the deposition mask of FIG. 5;

FIGS. 15 and 16 illustrate cross-sectional views of a method of fabricating the deposition mask of FIG. 6; and

FIGS. 17 through 20 illustrate cross-sectional views of a method of fabricating the deposition mask of FIGS. 1 through 3.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. The same reference numbers indicate the same components throughout the specification.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section.

Hereinafter, embodiments will be described with reference to the attached drawings.

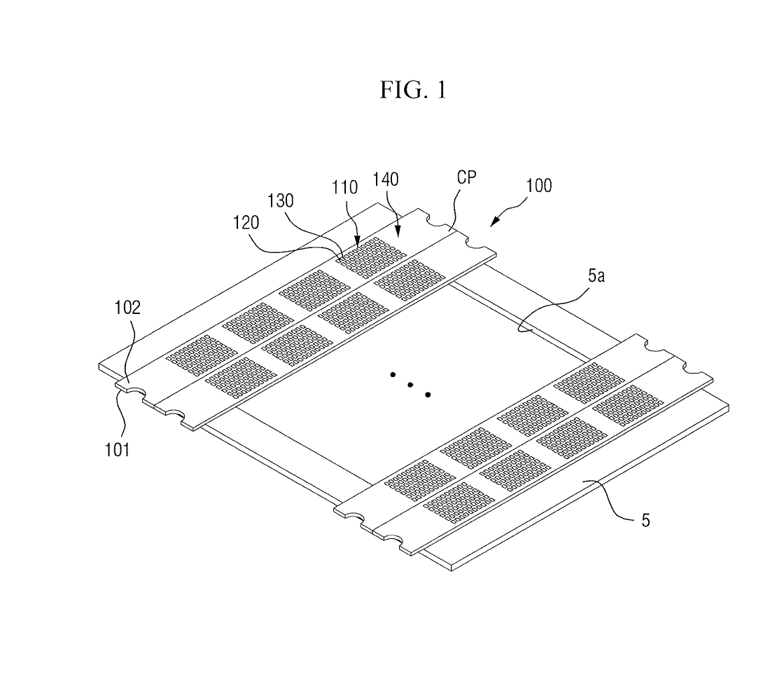

FIG. 1 illustrates a perspective view of a deposition mask 100 according to an embodiment.

Referring to FIG. 1, the deposition mask 100 according to the current embodiment may be placed on a mask frame 5 and coupled to the mask frame 5 by welding, and a mask assembly may be formed.

The mask frame 5 may form the exterior frame of the mask assembly and may be shaped like a quadrilateral band having a frame opening 5a in a central part thereof. The mask frame 5 may support the deposition mask 100 and may be coupled to the deposition mask 100 by welding. The mask frame 5 may be made of a metal material having high rigidity, such as stainless steel.

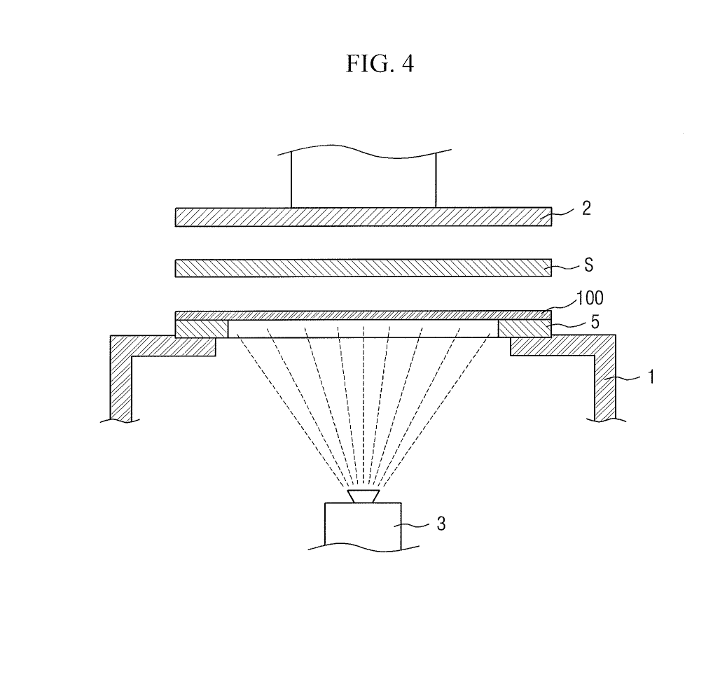

The deposition mask 100 may, on the whole, be shaped like a plate having a specific thickness. In the present specification, a surface of the plate will be referred to as a first surface 101, and the other surface which may face the above surface will be referred to as a second surface 102. The first surface 101 of the deposition mask 100 may contact an upper surface of the mask frame 5 when the deposition mask 100 is coupled to the upper surface of the mask frame 5 to cover the frame opening 5a of the mask frame 5. The second surface 102 of the deposition mask 100 may be placed to face a substrate S (see FIG. 4) when the substrate S (see FIG. 4) is placed on the deposition mask 100 to form a desired thin-film pattern by depositing a deposition material on the substrate S (see FIG. 4). The second surface 102 of the deposition mask 100 may contact the substrate S.

The deposition mask 100 may include clamping parts CP respectively protruding from both ends thereof. The clamping parts CP may be parts to which clamps may be coupled in order to stretch the deposition mask 100 in directions toward both ends of the deposition mask 100 before the deposition mask 100 is coupled to the mask frame 5 by welding, and the clamping parts CP may be cut off after the welding process.

The deposition mask 100 may be made of a mask material, for example, metal such as chrome (Cr), molybdenum (Mo), aluminum (Al), copper (Cu), titanium (Ti), tin (Sn), gold (Au), nickel (Ni), a nickel alloy, or a nickel-cobalt alloy. In FIG. 1, the deposition mask 100 consists of a plurality of masks. In an embodiment, the deposition mask 100 may also be formed as one mask having a size corresponding to the sum of sizes of the above masks.

The deposition mask 100 may include a deposition pattern part 110 and a fixing part 140. The deposition pattern part 110 may overlap the frame opening 5a when placed on the mask frame 50. The fixing part 140 may be disposed outside the deposition pattern part 110 and provide a space by which the deposition mask 100 may be coupled to the mask frame 5 by welding.

The deposition pattern part 110 will now be described in greater detail.

The deposition pattern part 110 may include a blocking part 120 and a plurality of pattern openings 130.

The blocking part 120 may block a deposition material when the deposition material is deposited on the substrate S (see FIG. 4) using the deposition mask 100. The blocking part 120 may be defined by the pattern openings 130 which will be described later and may roughly be shaped like a lattice when seen from above.

The pattern openings 130 may be surrounded by the blocking part 120. When a red organic light-emitting layer is formed on the substrate S (see FIG. 4) from among the red organic light-emitting layer, a green organic light-emitting layer, and a blue organic light-emitting layer of an organic light-emitting display device, the pattern openings 130 may be formed at locations corresponding to patterns of the red organic light-emitting layer, respectively. In FIG. 1, the pattern openings 130 are shaped like dots. In an embodiment, the pattern openings 130 may also be shaped like slits or a combination of dots and slits.

Each of the pattern openings 130 may include a first opening 131 and a second opening 132 disposed between the first surface 101 and the second surface 102 of the blocking part 120. The first opening 131 may be located relatively close to the first surface 101, and the second opening 132 may be located relatively close to the second opening 102. The first opening 131 and the second opening 132 may be connected to each other, and the pattern openings 130 may penetrate between the first surface 101 and the second surface 102.

The first opening 131 may become narrower from the first surface 101 of the blocking part 120 toward the second surface 102 and have a curved side surface. The second opening 132 may become narrower from the first opening 132 toward the second surface 102 and have a curved side surface which extends from the side surface of the first opening 131, and the pattern openings 130 may be wider at the first surface 101 than at the second surface 102.

In an exemplary embodiment, the side surface of the first opening 131 may be concave along a thickness direction, and the side surface of the second opening 132 may be convex along the thickness direction. An inflection point 133 may be located at a boundary between the side surface of the first opening 131 and the side surface of the second opening 132 when seen in cross-section.

A taper angle θ1 formed by a virtual plane, which connects the side surface of the first opening 131 located at the first surface 101 of the blocking part 120 and the side surface of the second opening 132 located at the second surface 102 of the blocking part 120, and a virtual plane which is parallel to the first surface 101 of the blocking part 120 may be approximately 45 degrees or less. If the taper angle θ1 is within this range, when a thin-film pattern is formed on the substrate S (see FIG. 4) using the deposition mask 100, the deposition of the deposition material outside an edge portion of the thin-film pattern may be reduced, and the non-uniformity of the thickness of the thin-film pattern due to, for example, a shadow phenomenon of the deposition mask 100, may be reduced.

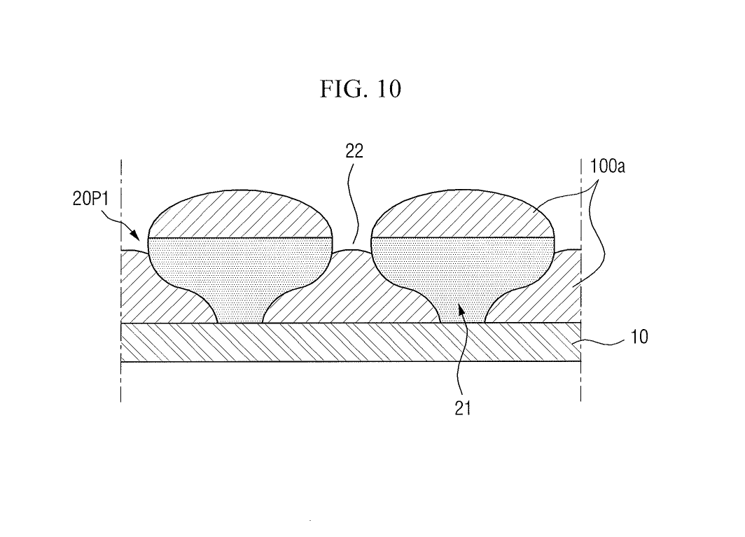

As described above, each of the pattern openings 130 may have a maximum width d1 at the first surface 101 of the blocking part 120 and a minimum width d2 at the second surface 102 of the blocking part 120. A difference between the maximum width d1 and the minimum width d2 of each of the pattern openings 130 may be approximately 3 μm or more. When the difference is approximately 3 μm or more, it may be easy to separate the mask material deposited on a photoresist pattern 20P1 (see FIG. 10) from the mask material deposited under the photoresist pattern 20P1 (see FIG. 10) in the process of fabricating the deposition mask 100, and a subsequent lift-off process may be made easy.

A thickness of the deposition mask 100, for example, a thickness t1 of the blocking part 120 may be approximately 1 to 20 μm. When the thickness of the deposition mask 100 is less than 1 μm, the rigidity of the deposition mask 100 may be low, and the deposition mask 100 may have low resistance to an external force. When the thickness of the deposition mask 100 exceeds 20 μm, it may be difficult to form the pattern openings 130 structured as described above, and it may be difficult to reduce the shadow phenomenon in a thin film formed by depositing the deposition material on the substrate S using the deposition mask 100.

While the second surface 102 of the blocking part 120 may be even, the first surface 101 of the blocking part 120 may be uneven. In the process of fabricating the deposition mask 100, a mask material layer 100a (see FIG. 10) may be formed by depositing the mask material on a base member 10 (see FIG. 10) using a deposition method such as a sputtering method. The mask material may be deposited unevenly within a photo opening 22 by the nature of the deposition process, and the first surface 101 of the blocking part 120 may be uneven. In an exemplary embodiment, the first surface 101 of the blocking part 120 may be a convex surface.

The deposition mask 100 configured as described above may be coupled to the mask frame 5 of FIG. 1 by welding, and the mask assembly, which may be used in a deposition process, may result.

FIG. 4 illustrates the configuration of a deposition device to describe a deposition process performed using the deposition mask 100 of FIG. 1.

Referring to FIG. 4, the deposition mask 100 and the mask frame 5 coupled to each other may be placed on a support 1. Then, the substrate S and the deposition mask 100 may be pressed against each other by driving a magnet unit 2. Each of the pattern openings 130 (see FIG. 3) may correspond to a particular pixel of the substrate S, for example, a pixel in which the red organic light-emitting layer may be formed, and the second opening 132 (see FIG. 3) may face the substrate S. Next, a deposition material may be evaporated from a crucible. The evaporated deposition material may pass through the first opening 131 (see FIG. 3) and the second opening 132 (see FIG. 3) sequentially to be deposited on the substrate S, and a thin-film pattern may be formed.

As described above, the deposition mask 100 according to the current embodiment may include the pattern openings 130, each having the first opening 131 and the second opening 132, and when a thin film is formed by depositing a deposition material on the substrate S, the deposition mask 100 structured as described above may minimize the shadow phenomenon which may occur when the deposition material is also deposited outside an edge portion of the thin film.

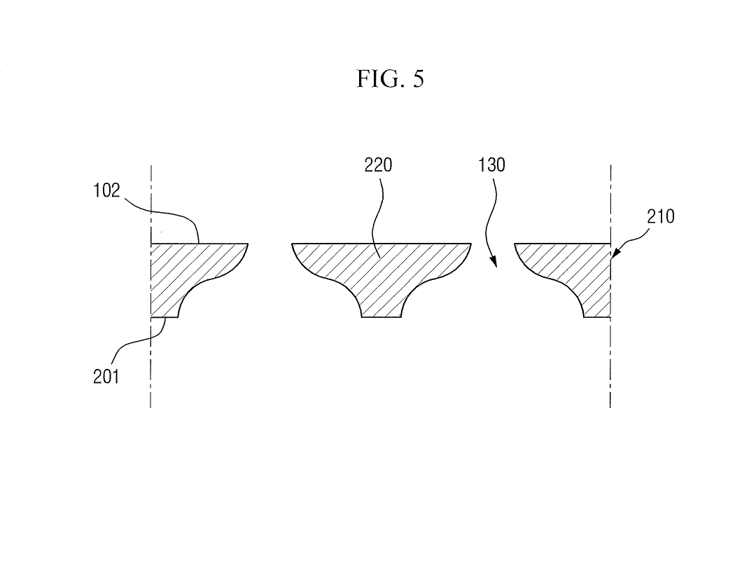

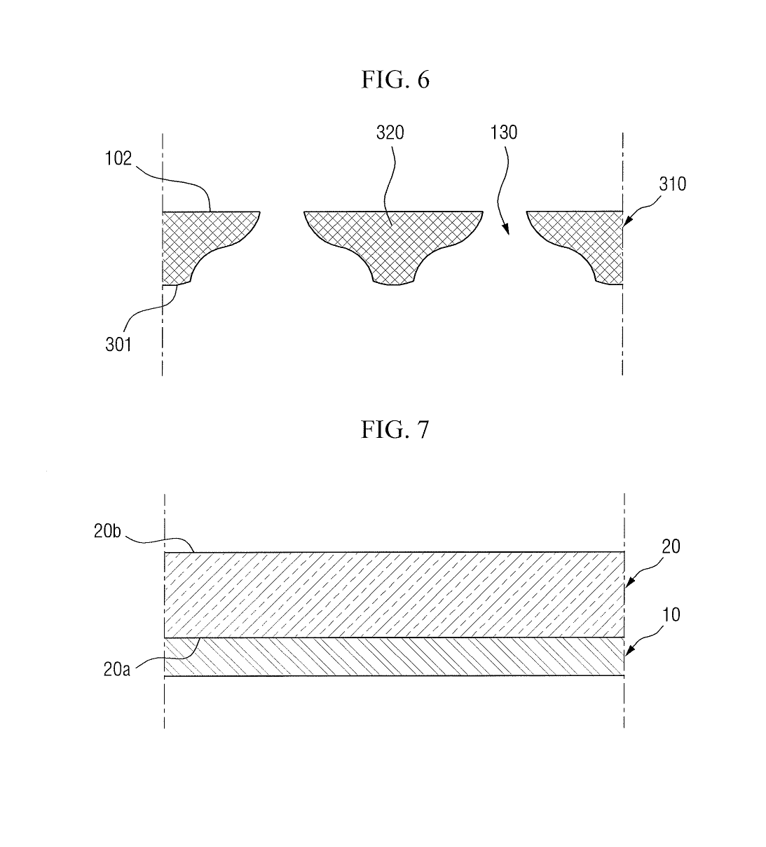

FIGS. 5 and 6 illustrate cross-sectional views of deposition masks according to various embodiments.

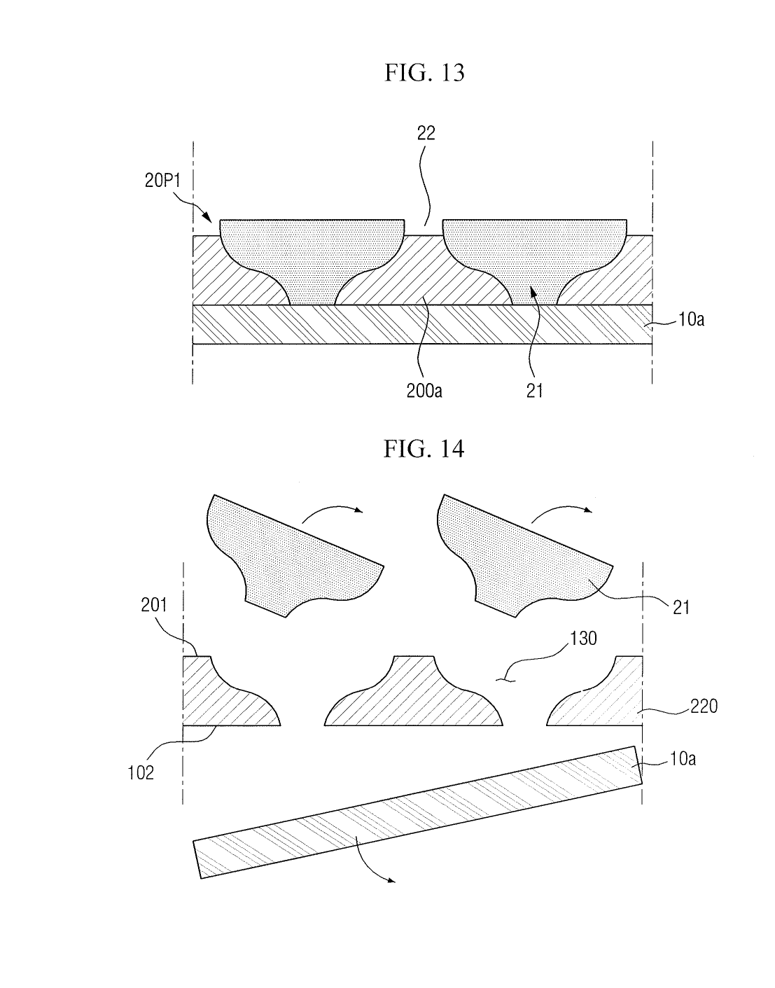

Referring to FIG. 5, a deposition pattern part 210 of a deposition mask may have a blocking part 220 and a plurality of pattern openings 130, and a first surface 201 of the blocking part 220 may be even. The first surface 201 of the blocking part 220 may be even because, for example, a mask material layer 200a (see FIG. 13) may be formed, in the process of forming the deposition mask, by plating a mask material on a surface of a base member 10a (see FIG. 13) within a photo opening 22 (see FIG. 13), which may correspond to the location of the blocking part 220 in a photoresist pattern 20P1 (see FIG. 13), using a plating method such as an electroplating method or an electroless plating method. For example, the mask material may be plated evenly on the surface of the member 10a (see FIG. 13) by the nature of the plating method.

The deposition mask including the deposition pattern part 210 having the blocking part 220 and the pattern openings 130 may provide the same effect as the deposition mask 100 of FIG. 3.

Referring to FIG. 6, a deposition pattern part 310 of a deposition mask may include a blocking part 320 and a plurality of pattern openings 130. The blocking part 320 may be made of an inorganic material. For example, a mask material of the deposition mask may be an inorganic material such as silicon nitride or silicon oxide. The deposition mask made of the inorganic material may have lower rigidity than the deposition mask 100 made of metal. The deposition mask made of the inorganic material may not be greatly affected by high-temperature heat, and the deposition mask may be less deformed at high temperature.

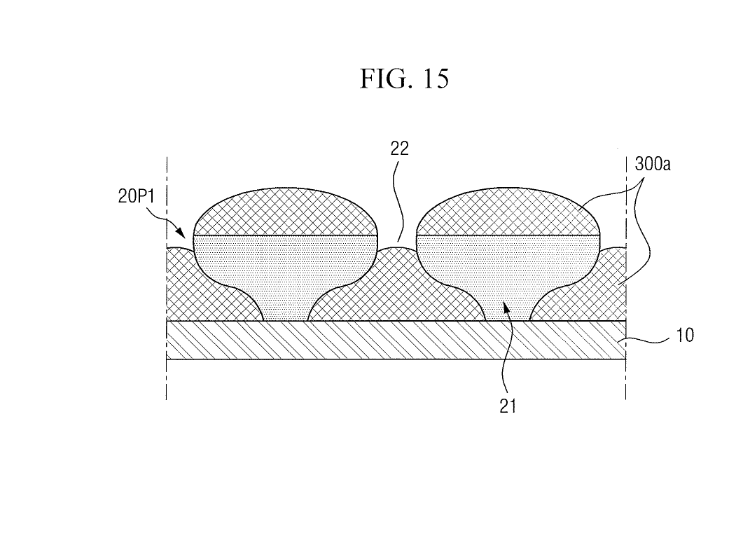

In the process of fabricating the deposition mask, a mask material 300a (see FIG. 15), i.e., the inorganic material may be deposited on a base member 10 (see FIG. 15) using a deposition method such as a chemical vapor deposition (CVD) method. The mask material 300a (see FIG. 15) may be deposited unevenly within a photo opening 22 (see FIG. 15) by the nature of the deposition process, and while a second surface 102 of the blocking part 320 may be even, a first surface 301 of the blocking part 320 may be uneven. In an exemplary embodiment, the first surface 301 of the blocking part 30 may be a convex surface.

The deposition mask including the deposition pattern part 310 having the blocking part 320 and the pattern openings 130 may provide the same effect as the deposition mask 100 of FIG. 3.

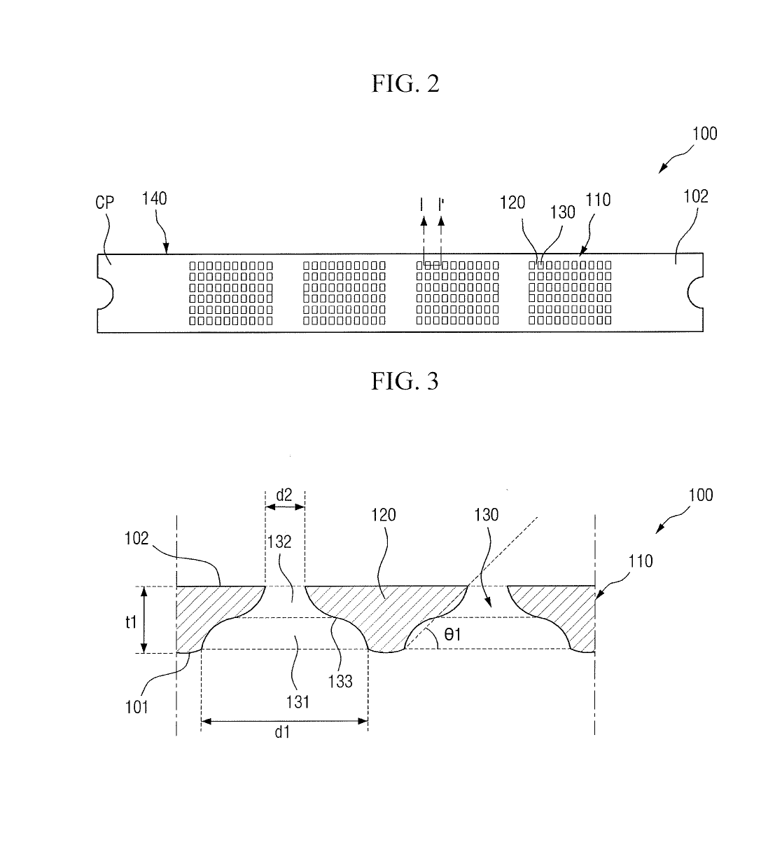

A method of fabricating the deposition mask 100 of FIGS. 1 through 3 will now be described.

FIGS. 7 through 11 illustrate cross-sectional views of a method of fabricating the deposition mask 100 of FIGS. 1 through 3.

Referring to FIG. 7, a photoresist material layer 20 may be formed on a base member 10. The base member 10 may be a substrate made of metal, glass, or polymer. The photoresist material layer 20 may include a first surface 20a which may contact the base member 10 and a second surface 20b which may face the first surface 20a. The photoresist material layer 20 may be made of e.g., include, a negative photoresist material.

The negative photoresist material may contain a binder, a photosensitizer, a solvent, and an additive.

The binder may contain novolac resin and acrylate.

The novolac resin may be a polymer which may be compounded by causing aromatic alcohol, such as meta- and/or para-cresol, to react with formaldehyde. The novolac resin may have a molecular weight of 2000 to 9000 and contain meta-cresol and para-cresol in a ratio of 20:80 to 80:20 by weight. The acrylate may be an acrylic copolymer obtained by copolymerizing a monomer such as unsaturated carboxylic acid, unsaturated carboxylic acid anhydride, or a mixture thereof. Examples of the acrylate may include acrylic acid, methacrylic acid, and maleic anhydride.

The photosensitizer may be a compound which may generate radicals that polymerize an ethylenic unsaturated group in response to the irradiation of light having a wavelength of approximately 300 to 450 μm. The photosensitizer may be one of a halomethylated triazine derivative, a halomethylated oxadiazole derivative, an imidazole derivative, benzoin, benzoin alkyl ether, an anthraquinone derivative, a benzanthrone derivative, a benzophenone derivative, an acetophenone derivative, a thioxanthone derivative, a benzoic acid ester derivative, an acridine derivative, a phenazine derivative, a titanocene derivative, an a-aminoalkyl phenone compound, an acyiphosphin oxide compound, and an oxime ester derivative.

The halomethylated triazine derivative may be one of 2-(4-methoxyphenyl)-4,6-bis(trichloromethyl)-s-triazine; 2-(4-methoxynaphthyl)-4,6-bis(trichloromethyl)-s-triazine; 2-(4-ethoxynaphthyl)-4,6-bis(trichloromethyl)-s-triazine; and 2-(4-ethoxycarbonylnaphthyl)-4,6-bis (trichloromethyl)-s-triazine.

The imidazole derivative may be one of 2-(o-chlorophenyl)-4,5-diphenylimidazole dimer; 2-(o-chlorophenyl)-4,5-bis(3′-methoxyphenyl) imidazole dimer; 2-(o-fluorophenyl)-4,5-diphenylimidazole dimer; 2-(o-methylphenyl)-4,5-diphenylimidazole dimer; and 2-(o-methoxyphenyl)-4,5-diphenylimidazole dimer.

The benzoin may be one of benzoin methyl ether, benzoin phenyl ether, benzoin isobutyl ether, and benzoin isopropyl ether.

The anthraquinone derivative may be one of 2-methylanthraquinone, 2-ethylanthraquinone, 2-t-butylanthraquinone, and 1-chloroanthraquinone.

The benzophenone derivative may be one of benzophenone, Michler's ketone, 2-methylbenzophenone, 3-methylbenzophenone, 4-methylbenzophenone, 2-chlorobenzophenone, 4-bromobenzophenone, and 2-carboxybenzophenone.

The acetophenone derivative may be one of 2,2-dimethoxy-2-phenylacetophenone, 2,2-diethoxyacetophenone, 1-hydroxycyclohexylphenylketone, α-hydroxy-2-methylphenylpropanone, 1-hydroxy-1-methylethyl-(p-isopropylphenyl)ketone, 1-hydroxy-1-(p-dodecylphenyl)ketone, 2-methyl-(4′-(methylthio)phenyl)-2-morpholino-1-propanone, and 1,1,1-trichloromethyl-(p-butylphenyl)ketone.

The thioxanthone derivative may be one of thioxanthone, 2-ethylthioxanthone, 2-isopropylthioxanthone, 2-chlorothioxanthone, 2,4-dimethylthioxanthone, 2,4-diethylthioxanthone, and 2,4-diisopropylthioxanthone.

The benzoic acid ester derivative may be one of ethyl p-dimethylaminobenzoate and ethyl p-diethylaminobenzoate.

The acridine derivative may be one of 9-phenylacridine and 9-(p-methoxyphenyl)acridine.

The phenazine derivative may be 9,10-dimethylbenzphenazine.

The titanocene derivative may be one of dicyclopentadienyl-titanium-dichloride; dicyclopentadienyl-titanium-bisphenyl; dicyclopentadienyl-titanium-bis(2,3,4,5,6-pentafluorophen-1-yl); dicyclopentadienyl-titanium-bis(2,3,5,6-tetrafluorophen-1-yl); dicyclopentadienyl-titanium-bis(2,4,6-trifluorophen-1-yl); dicyclopentadienyl-titanium-bis(2,6-difluorophen-1-yl); dicyclopentadienyl-titanium-bis(2,4-difluorophen-1-yl); di(methylcyclopentadienyl)-titanium-bis(2,3,4,5,6-pentafluorophen-1-yl); di(methylcyclopentadienyl)-titanium-bis(2,6-difluorophen-1-yl); and dicyclopentadienyl-titanium-bis[2,6-difluoro-3-(pyrro-1-yl)phen-1-yl].

The a-aminoalkyl phenone compound may be one of 2-methyl-1-[4-(methylthio)phenyl]-2-morpholinopropan-1-yl; 2-benzyl-2-dimethylamino-1-(4-morpholinophenyl)butanone-1-on; 4-dimethylaminoethylbenzoate; 4-dimethylaminopropiophenone; 2-ethylhexyl-1,4-dimethylaminobenzoate; 2,5-bis(4-biethylaminobenzal)cyclohexanone; 7-diethylamino-3-(4-diethylaminobenzoyl)cumarine; and 4-(diethylamino)chalcone.

The acylphosphine oxide compound may be one of 2,4,6-trimethylbenzoyl-diphenyl-phosphine oxide; and bis(2,4,6-trimethylbenzoyl)-phenylphosphine oxide.

The oxime ester compound may be one of 1,2-octanedione, 1-[4-(phenylthio)phenyl]-2-(o-benzoyloxime); ethanone; or 1-[9-ethyl-6-(2-methylbenzoyl)-9H-carbazol-3-yl], and 1-(o-acetyloxime).

The solvent may be a solvent that may dissolve and disperse the binder and the photosensitizer. For example, the solvent may be one of methyl cellosolve, ethyl cellosolve, butyl cellosolve, diethylene glycol monomethyl ether, propylene glycol monoacetate, propylene glycol diacetate, propylene glycol monomethyl ether acetate (PGMEAc), methyl ethyl ketone, methyl isobutyl ketone, cyclohexanone, toluene, chloroform, dichloromethane, ethyl acetate, methyl lactate, ethyl lactate, 3-methoxymethyl propionate, 3-ethoxyethyl propionate, propylene glycol monomethyl ether, methanol, ethanol, propanol, butanol, tetrahydrofuran, diethylene glycol dimethyl ether, methoxybutyl ester acetate, Solvesso™, and carbitol.

The additive may be a compound that may maintain the negative photoresist material stably by absorbing (capturing) the radicals. Examples of the additive may include sterically hindered phenolics and sterically hindered amines (HALS). Product names of the additive may include TINUVIN® 123 and TINUVIN®144.

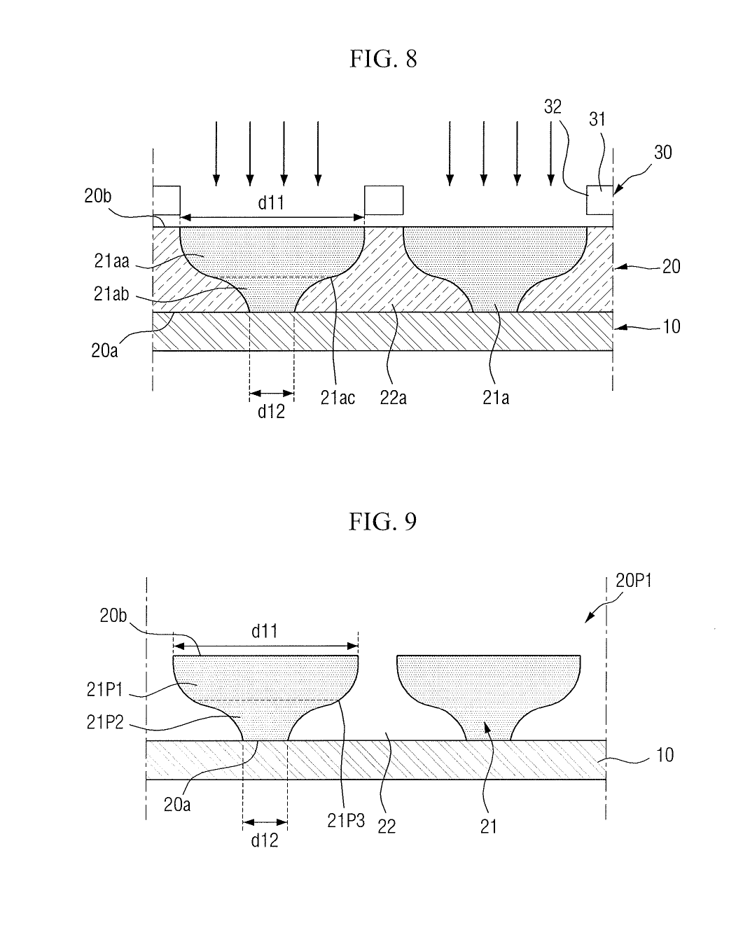

The additive may adjust the curing of the photoresist material layer 20 in a light irradiation process of FIG. 8 performed to form a photoresist pattern 20P1 of FIG. 9. For example, when light is irradiated to the photoresist material layer 20 in FIG. 8, first light energy may be irradiated to an upper part of the photoresist material layer 20, and second light energy lower than the first light energy may be irradiated to a lower part of the photoresist material layer 20 by the nature of light irradiation. The additive may absorb (capture) radicals generated by the second light energy before the radicals generated by the second light energy actively form the cross-linkage of the binder. In so doing, the additive may reduce the curing of the lower part of the photoresist material layer 20 which may occur as a result of reacting to the light. The additive may be added in an amount of approximately 5 to 30% by weight based on 100% by weight of the photosensitizer. When added in an amount of less than 5% by weight based on 100% by weight of the photosensitizer, the additive may hardly absorb (capture) the radicals. When added in an amount of more than 30% by weight based on 100% by weight of the photosensitizer, the additive may excessively absorb the radicals generated by the photosensitizer, and the ability of the photosensitizer to form a photoresist pattern may be may undermined.

Referring to FIGS. 8 and 9, the photoresist pattern 20P1 including photo patterns 21 and a photo opening 22 may be formed on the base member 10.

For example, referring to FIG. 8, a photomask 30 including a light-blocking part 31 and light-transmitting parts 32 may be placed on the photoresist material layer 20. The light-blocking part 31 of the photomask 30 may correspond to an area in which the blocking part 120 of FIG. 3 may be formed, and the light-transmitting parts 32 may correspond to areas in which the pattern openings 130 of FIG. 3 may be formed. The first surface 20a of the photoresist material layer 20 may correspond to the second surface 102 (see FIG. 3) of the blocking part 120 (see FIG. 3), and the second surface 20b of the photoresist material layer 20 may correspond to the first surface 101 (see FIG. 3) of the blocking part 120 (see FIG. 3).

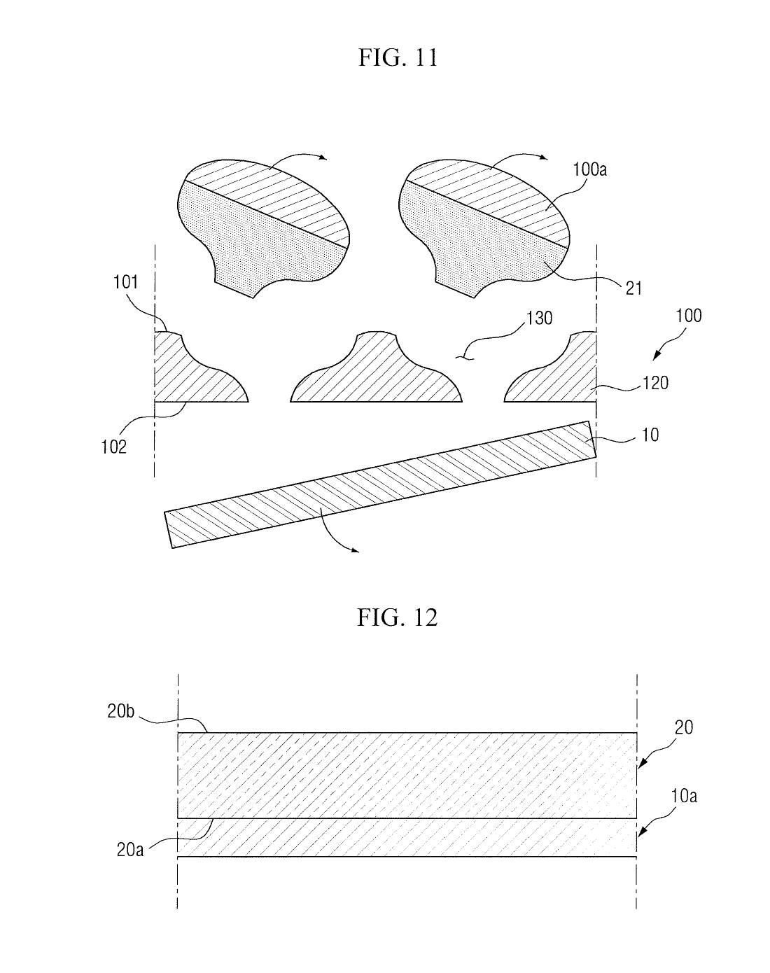

Next, light may be irradiated to the photoresist material layer 20 using the photomask 30, and a first area 21a of the photoresist material layer 20 which may correspond to each of the light-transmitting parts 32 may be cured by reacting to the light (i.e., the cross-linkage of the binder may be formed in the first area 21a), and a second area 22a of the photoresist material layer 20 which may correspond to the light-blocking part 31 may not react to the light. The first area 21a may be an area formed by irradiating light from the second surface 20b of the photoresist material layer 20 toward the first surface 20a. The first area 21a may have a maximum width d11 at the second surface 20b of the photoresist material layer 20 and a minimum width d12 at the first surface 20a of the photoresist material layer 20. For example, the first area 21a may be inversely tapered. A difference between the maximum width d11 and the minimum width d12 may be approximately 3 μm or more. A mask material deposited on the photo patterns 21 of the photoresist pattern 20P1 may be easily separated from the mask material deposited on the base member 10 within the photo opening 22, and the photo patterns 21 may be be easily removed using a lift-off method in FIG. 11.

The first area 21a may have a first part 21aa and a second part 21ab. The first part 21aa may become narrower from the second surface 20b of the photoresist material layer 20 toward the first surface 20a and have a curved side surface. The second part 21ab may become narrower from the first part 21aa toward the first surface 20a of the photoresist material layer 20 and have a curved surface which extends from the side surface of the first part 21aa. In an exemplary embodiment, the side surface of the first part 21aa may be concave along a thickness direction, and the side surface of the second part 21ab may be convex along the thickness direction. When seen in cross-section, an inflection point 21ac may be located at a boundary between the side surface of the first part 21aa and the side surface of the second part 21ab. The first area 21a structured as described above may be formed by adjusting the weight of the additive based on the weight of the photosensitizer in the negative photoresist material used to form the photoresist material layer 20.

Next, the photoresist material layer 20 may be developed to produce the photoresist pattern 20P1 as illustrated in FIG. 9. For example, the photoresist pattern 20P1 including the photo patterns 21 and the photo opening 22 may be formed. A first surface of each of the photo patterns 21 may correspond to the first surface 20a of the photoresist material layer 20 of FIG. 8, and a second surface of each of the photo patterns 21 may correspond to the second surface 20b of the photoresist material layer 20 of FIG. 8. The first surface of each of the photo patterns 21 will hereinafter be indicated by reference character ‘20a,’ and the second surface of each of the photo patterns 21 will hereinafter be indicated by reference character ‘20b.’ The photo opening 22 may be defined by the photo patterns 21 and formed in substantially a lattice shape when seen from above.

Each of the photo patterns 21 may have a first photo pattern 21P1 and a second photo pattern 21P2. The first photo pattern 21P1 may become narrower from the second surface 20b toward the first surface 20a and have a curved side surface, and the second photo pattern 21P2 may become narrower from the first photo pattern 21P1 toward the first surface 20a and have a curved side surface which extends from the side surface of the first photo pattern 21P1. An inflection point 21P3 may be located at a boundary between the side surface of the first photo pattern 21P1 and the side surface of the second photo pattern 21P2.

Each of the photo patterns 21 which may correspond to the first areas 21a of FIG. 8 may have a maximum width d11 at the second surface 20b and a minimum width d12 at the first surface 20a. A difference between the maximum width d11 and the minimum width d12 of each of the photo patterns 21 may be approximately 3 μm or more.

Referring to FIG. 10, a mask material may be deposited from the side of the photoresist pattern 20P1, and a mask material layer 100a may be formed on the photo patterns 21 and in the photo opening 22. The mask material layer 100a deposited on the photo patterns 21 may be separated from the mask material layer 100a deposited in the photo opening 22, and an upper side surface of each of the photo patterns 21 may not be covered by the mask material layer 100a and may be easily removed by a stripper in a subsequent lift-off process. Even if the mask material layer 100a deposited on the photo patterns 21 and the mask material layer 100a deposited in the photo opening 22 are not completely separated from each other, the lift-off process may still be performed, despite a reduction in efficiency and reliability, as long as part of the upper side surface of each of the photo patterns 21 is not covered by the mask material layer 100a.

The mask material may be the metal material described above, and the deposition of the mask material may be performed using a deposition method such as a sputtering method. The mask material may be deposited on the base member 10 such that the mask material layer 100a formed in the photo opening 22 has a thickness of approximately 1 to 20 μm.

A tapered space may be formed in the photo opening 22, the mask material may be deposited and grown from the surface of the base member 10 at a different speed at each location, and the deposited mask material layer 100a may have an uneven surface. In the drawing, the surface of the mask material layer 100a is convex because the mask material is deposited and grown fast in a central part of the photo opening 22. In an embodiment, the mask material layer 100a may have a different uneven shape according to a deposition method or condition.

Referring to FIG. 11, the photo patterns 21 may be removed while the mask material layer 100a is left on the base member 10, and the result may be a deposition mask 100 including a blocking part 120 formed of the mask material layer 100a remaining on the base member 10 and a plurality of pattern openings 130 defined by the blocking part 120. After the formation of the deposition mask 100, the base member 10 may be removed. The photo patterns 21 on which the mask material layer 100a may be formed may be removed by a lift-off process using a stripper.

As described above, in the method of fabricating the deposition mask 100 of FIGS. 1 through 3, the photoresist pattern 20P1 may be formed by patterning the negative photoresist material layer 20 which may contain the additive that may absorb (captures) radicals. Then, the mask material layer 100a may be formed on the base member 10 by depositing a mask material on the base member 10 using the photoresist pattern 20P1. Finally, the photo patterns 21 and the base member 10 on which the mask material layer 100a may be formed may be removed, the deposition mask 100 (see FIG. 3) having the pattern openings 130 of a desired shape at desired locations may be fabricated, and the process of fabricating the deposition mask 100 (see FIG. 3) may be simplified.

FIGS. 12 through 14 illustrate cross-sectional views of a method of fabricating the deposition mask of FIG. 5.

The method of fabricating the deposition mask of FIG. 5 is similar to the fabrication method described above with reference to FIGS. 7 through 11 except that a photoresist material layer 20 is formed on a base member 10a, that a mask material layer 200a is formed on the base member 10a, and that photo patterns 21 and the base member 10a are removed. A description of the method of fabricating the deposition mask of FIG. 5 will be made only on forming the photoresist material layer 20 on the base member 10a, forming the mask material layer 200a on the base member 10a, and removing the photo patterns 21 and the base member 10a.

Referring to FIG. 12, the photoresist material layer 20 may be formed on the base member 10a. The base member 10a may be a metal substrate that may allow the mask material layer 200a to be formed by plating a mask material on the base member 10a using a plating method. The specific configuration of the photoresist material layer 20 and forming a photoresist pattern 20P1 using the photoresist material layer 20 have been described above in detail with reference to FIGS. 7 and 9, and a redundant description thereof is omitted.

Referring to FIG. 13, a mask material may be plated on the base member 10a using a plating method such as an electroplating method or an electroless plating method, and the mask material layer 200a may be formed only on the base member 10a within a photo opening 22. The mask material may be the metal material described above. The mask material may be plated on the base member 10a such that the mask material layer 200a formed in the photo opening 22 has a thickness of approximately 1 to 20 μm. The plated mask material layer 200a may have an even surface.

Referring to FIG. 14, the photo patterns 21 may be removed while the mask material layer 200a is left on the base member 10a, and the result may be a deposition mask including a blocking part 220 formed of the mask material layer 200a remaining on the base member 10a and a plurality of pattern openings 130 defined by the blocking part 220. After the formation of the deposition mask, the base member 10a may be removed. The photo patterns 21 may be removed by a process using a stripper.

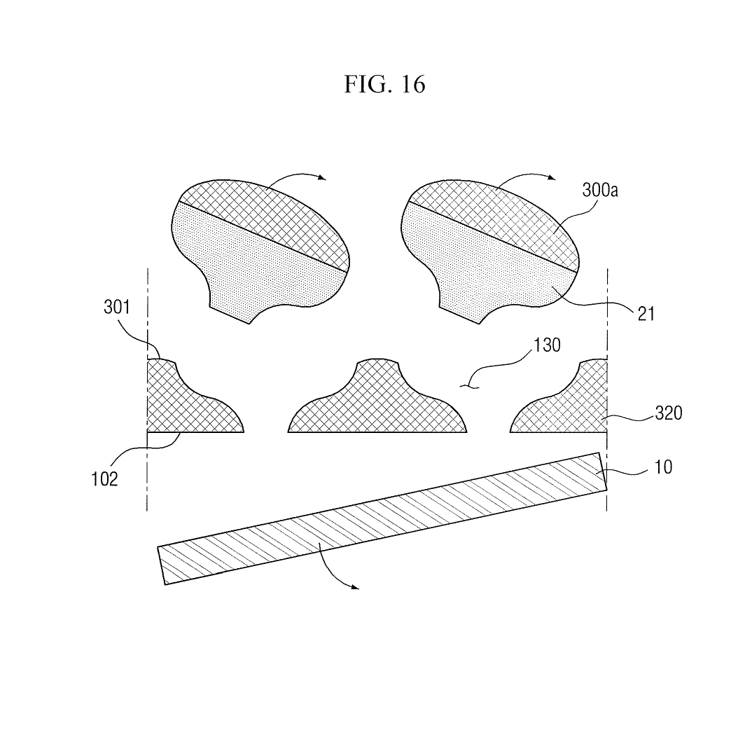

FIGS. 15 and 16 illustrate cross-sectional views of a method of fabricating the deposition mask of FIG. 6.

The method of fabricating the deposition mask of FIG. 6 is similar to the fabrication method described above with reference to FIGS. 7 through 11 except that a mask material layer 300a is formed on a base member 10 and that photo patterns 21 and the base member 10 are removed. A description of the method of fabricating the deposition mask of FIG. 6 will be made only on depositing the mask material layer 300a and removing the photo patterns 21 and the base member 10.

Referring to FIG. 15, a mask material may be deposited from the side of a photoresist pattern 20P1, and the mask material layer 300a may be formed on the photo patterns 21 and in a photo opening 22.

The mask material layer 300a deposited on the photo patterns 21 may be separated from the mask material layer 300a deposited in the photo opening 22, and an upper side surface of each of the photo patterns 21 may not be covered by the mask material layer 300a and may be easily removed by a stripper in a subsequent lift-off process. Even if the mask material layer 300a deposited on the photo patterns 21 and the mask material layer 300a deposited in the photo opening 22 are not completely separated from each other, the lift-off process may still be performed, despite a reduction in efficiency and reliability, as long as part of the upper side surface of each of the photo patterns 21 is not covered by the mask material layer 300a.

The mask material may be the inorganic material described above, and the deposition of the mask material may be performed using a deposition method such as a CVD method. The mask material may be deposited on the base member 10 such that the mask material layer 300a formed in the photo opening 22 has a thickness of approximately 1 to 20 μm.

A tapered space may be formed in the photo opening 22, the mask material may be deposited and grown from the surface of the base member 10 at a different speed at each location, and the deposited mask material layer 300a may have an uneven surface. In the drawing, the surface of the mask material layer 300a is convex because the mask material is deposited and grown fast in a central part of the photo opening 22. In an embodiment, the mask material layer 300a may have a different uneven shape according to a deposition method or condition.

Referring to FIG. 16, the photo patterns 21 may be removed while the mask material layer 300a is left on the base member 10, and the result may be a deposition mask including a blocking part 320 formed of the mask material layer 300a remaining on the base member 10 and a plurality of pattern openings 130 defined by the blocking part 320. After the formation of the deposition mask, the base member 10 may be removed. The photo patterns 21 on which the mask material layer 300a may be formed may be removed by a lift-off process using a stripper.

A method of fabricating the deposition mask 100 of FIGS. 1 through 3 will now be described.

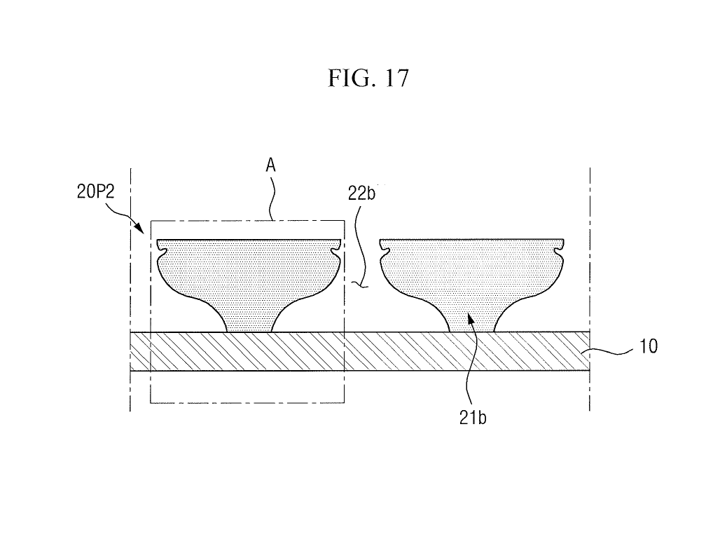

FIGS. 17 through 20 illustrate cross-sectional views of a method of fabricating the deposition mask 100 of FIGS. 1 through 3.

The current method of fabricating the deposition mask 100 of FIGS. 1 through 3 is similar to the fabrication method described above with reference to FIGS. 7 through 11 except that a photoresist pattern 20P2 is formed, that a mask material layer 100a is formed on a base member 10, and that photo patterns 21b and the base member 10 are removed. A description of the current method of fabricating the deposition mask 100 of FIGS. 1 through 3 will be made only on forming the photoresist pattern 20P2, forming the mask material layer 100a, and removing the photo patterns 21b and the base member 10.

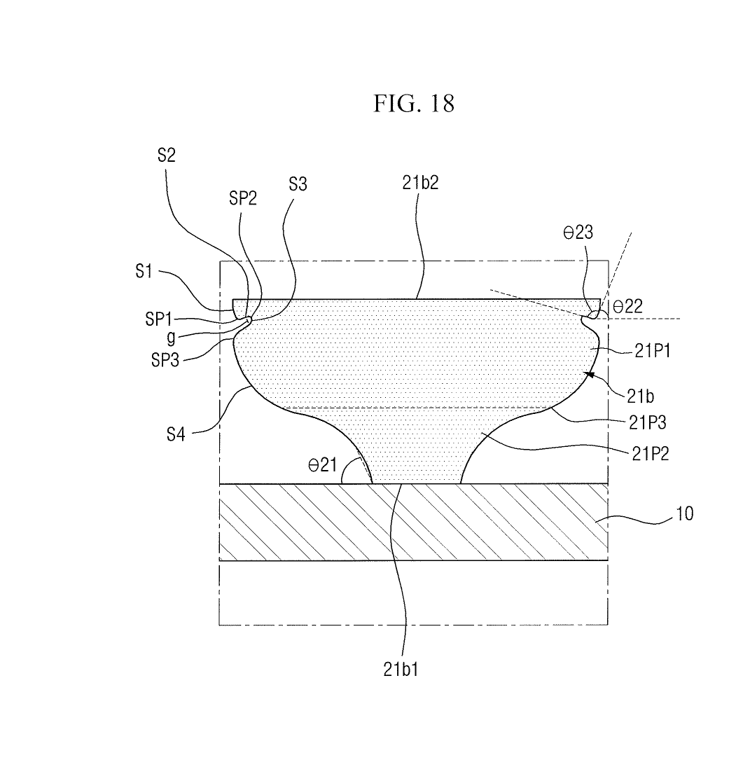

Referring to FIGS. 17 and 18, the photoresist pattern 20P2 including the photo patterns 21b and a photo opening 22b may be formed on the base member 10.

The process of forming the photoresist pattern 20P2 is similar to the process of forming the photoresist pattern 20P1 described above with reference to FIGS. 7 and 8, and each of the photo patterns 21b of the photoresist pattern 20P2 may have a first photo pattern 21P1 and a second photo pattern 21P2. The first photo pattern 21P1 may become narrower from a second surface 21b2 toward a first surface 21b1 and have a curved surface. The second photo pattern 21P2 may become narrower from the first photo pattern 21P1 toward the first surface 21b1 and have a curved side surface which extends from the side surface of the first photo pattern 21P1. An inflection point 21P3 may be located at a boundary between the side surface of the first photo pattern 21P1 and the side surface of the second photo pattern 21P2.

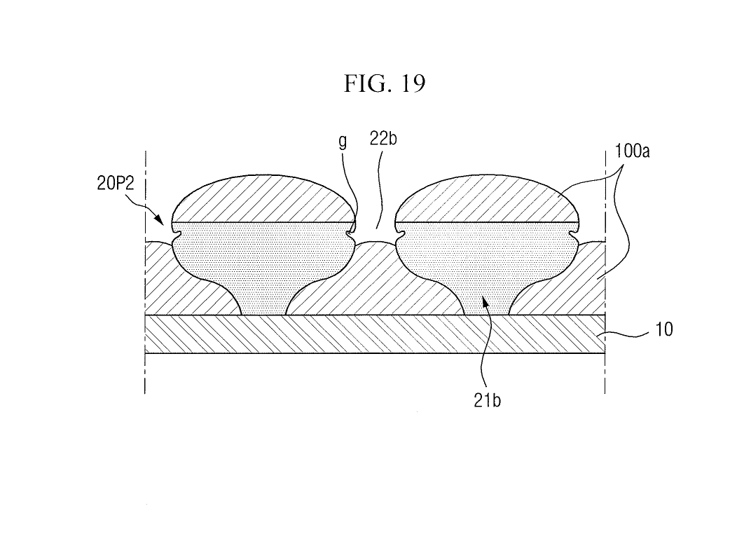

The side surface of the first photo pattern 21P1 may include a first side surface S1, a second side surface S2, a third side surface S3 and a fourth side surface S4 continuous from the second surface 21b2 of each of the photo patterns 21b, and inflection points (SP1, SP2, SP3) may respectively be located at a boundary between the first side surface S1 and the second side surface S2, at a boundary between the second side surface S2 and the third side surface S3, and at a boundary between the third side surface S3 and the fourth side surface S4. The inflection points (SP1, SP2, SP3) may be a first inflection point SP1, a second inflection point SP2, and a third inflection point SP3. A separation groove g may be defined by the second side surface S2 and the third side surface S3. In FIG. 19, a mask material may be deposited from the side of the photoresist pattern 20P2, and the mask material layer 100a formed on the photo patterns 21b may be separated from the mask material layer 100a formed on the base member 10 in the photo opening 22b by the separation groove g. This is because the first inflection point SP1 of each of the photo patterns 21b may prevent the mask material deposited on the photo pattern 21b from being connected to the mask material deposited in the photo opening 22b. The mask material may be deposited from on each of the photo patterns 21b up to the first side surface S1. It may be difficult for the mask material to be deposited up to the second side surface S2 via the first inflection point SP1.

An angle θ21 between the first surface 21b1 of each of the photo patterns 21b and the side surface of the second photo pattern 21P2 adjacent to the first surface 21b1 may be less than approximately 90 degrees. An angle θ22 between a virtual plane parallel to the second surface 21b2 of each of the photo patterns 21b and the first side surface S1 of the first photo pattern 21P1 may be less than approximately 90 degrees. An angle θ23 between the first side surface S1 and the second side surface S2 of the first photo pattern 21P1 may be approximately 90 degrees or more.

The photo patterns 21b structured as described above may be realized by adjusting the exposure of the photoresist material layer 20 in FIG. 8.

Referring to FIG. 19, a mask material may be deposited from the side of the photoresist pattern 20P2, and a mask material layer 100a may be formed on the photo patterns 21b and in the photo opening 22b. The mask material layer 100a formed on the photo patterns 21b may be separated from the mask material layer 100a formed in the photo opening 22b, and an upper side surface of each of the photo patterns 21b may not be covered by the mask material layer 100a and may be easily removed by a stripper in a subsequent lift-off process.

The mask material may be the inorganic material described above, and the deposition of the mask material may be performed using a deposition method such as a sputtering method. The mask material may be deposited on the base member 10 such that the mask material layer 100a formed in the photo opening 22b has a thickness of approximately 1 to 20 μm.

A tapered space may be formed in the photo opening 22b, the mask material may be deposited and grown from the surface of the base member 10 at a different speed at each location, and the deposited mask material layer 100a may have an uneven surface. In the drawing, the surface of the mask material layer 100a is convex because the mask material is deposited and grown fast in a central part of the photo opening 22b. In an embodiment, the mask material layer 100a may have a different uneven shape according to a deposition method or condition.

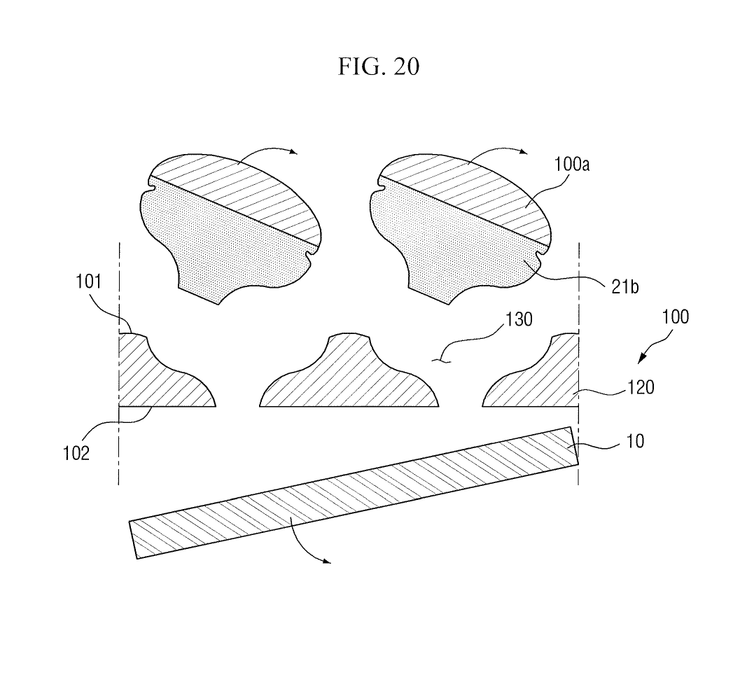

Referring to FIG. 20, the photo patterns 21b may be removed while the mask material layer 100a is left on the base member 10, and the result may be a deposition mask 100 including a blocking part 120 formed of the mask material layer 100a remaining on the base member 10 and a plurality of pattern openings 130 defined by the blocking part 120. After the formation of the deposition mask 100, the base member 10 may be removed. The photo patterns 21b on which the mask material layer 100a may be formed may be removed by a lift-off process using a stripper.

By way of summation and review, to fabricate an organic light-emitting display device using a deposition method, a deposition mask (e.g., a fine metal mask (FMM)) having pattern openings identical to patterns of a thin film which may be formed on a substrate may be pressed against the substrate. Then, a deposition material may be deposited on the substrate through the deposition mask, and a thin film of a desired pattern may be formed.

A deposition mask may be fabricated by forming pattern openings in a metal base member using a wet-etching method or by forming the pattern openings in the metal base member using a laser irradiation method.

A pattern opening may have a particular shape, for example, a particular tapered shape in order to prevent a deposition material deposited on a substrate using a deposition mask to form a thin film from being deposited on an edge portion of the thin film.

When a deposition mask is fabricated using a wet-etching method, it may be difficult to precisely form pattern openings in a particular shape due to, for example, the non-uniformity of an etching process. A wet-etching process may be performed twice, the process of forming the pattern openings may be complicated, and the time required to form the pattern openings may be increased.

When pattern openings of a deposition mask are formed using a laser irradiation method, a metal base member may be deformed by the heat of laser light in a laser irradiation process, or the pattern openings may be formed at unwanted locations due to, for example, the vibration of the laser light.

Embodiments may provide a method of fabricating a deposition mask which may have pattern openings of a desired shape at desired locations and may be fabricated simply. Embodiments may also provide a deposition mask which may have pattern openings of a desired shape at desired locations and may be fabricated simply.

A method of fabricating a deposition mask according to an embodiment may be employed to fabricate a deposition mask having pattern openings of a desired shape at desired locations. The method may simplify the process of fabricating the deposition mask.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of fabricating a deposition mask, the method comprising:
forming a photoresist pattern on a base member, the photoresist pattern having a plurality of inversely tapered photo patterns and a photo opening defined by the photo patterns;
forming a mask material layer in the photo opening and on the photo patterns;
removing the photo patterns and the mask material layer formed on the photo patterns, leaving the mask material layer formed in the photo opening; and
removing the base member.

2. The method as claimed in claim 1, wherein:
each of the photo patterns has a first surface contacting the base member and a second surface facing the first surface,
each of the photo patterns includes a first photo pattern becoming narrower from the second surface toward the first surface, the first photo pattern having a curved side surface, and a second photo pattern becoming narrower from the first photo pattern toward the first surface, the second photo pattern having a curved side surface extending from the curved side surface of the first photo pattern, and
an inflection point is located at a boundary between the curved side surface of the first photo pattern and the curved side surface of the second photo pattern.

3. The method as claimed in claim 2, wherein:
each of the photo patterns has a maximum width at the second surface and a minimum width at the first surface, and
a difference between the maximum width and the minimum width is 3 μm or more.

4. The method as claimed in claim 1, wherein the mask material layer has a thickness of 1 to 20 μm.

5. The method as claimed in claim 1, wherein forming the mask material layer includes depositing a metal material or an inorganic material on the base member having the photoresist pattern using a deposition method.

6. The method as claimed in claim 1, wherein in forming the mask material layer, the mask material layer formed in the photo opening is separated from the mask material layer formed on the photo patterns.

7. The method as claimed in claim 2, wherein each of the photo patterns further includes a separation groove in the curved side surface of the first photo pattern, the separation groove being located higher than the mask material layer.

8. The method as claimed in claim 7, wherein:
the curved side surface of the first photo pattern includes a first side surface, a second side surface, a third side surface, and a fourth side surface, which are continuous from the second surface of each of the photo patterns,
inflection points are respectively located at a boundary between the first side surface and the second side surface, at a boundary between the second side surface and the third side surface, and at a boundary between the third side surface and the fourth side surface, and
the separation groove is defined by the second side surface and the third side surface.

9. The method as claimed in claim 1, wherein:
forming the photoresist pattern includes patterning a photoresist material layer formed on the base member, and
the photoresist material layer includes a negative photoresist material, which contains a binder, a photosensitizer, a solvent, and an additive that captures radicals generated by the photosensitizer in response to irradiation of light.

10. The method as claimed in claim 9, wherein the additive is added in an amount of 5 to 30% by weight based on 100% by weight of the photosensitizer.

11. A method of fabricating a deposition mask, the method comprising:
forming a photoresist pattern on a base member, the photoresist pattern having a plurality of inversely tapered photo patterns and a photo opening defined by the photo patterns;
forming a mask material layer in the photo opening;
removing the photo patterns, leaving the mask material layer formed in the photo opening; and
removing the base member,
each of the photo patterns having a first surface contacting the base member and a second surface facing the first surface, each of the photo patterns including a first photo pattern becoming narrower from the second surface toward the first surface, the first photo pattern having a curved side surface, and a second photo pattern becoming narrower from the first photo pattern toward the first surface, the second photo pattern having a curved side surface extending from the curved side surface of the first photo pattern, an inflection point being located at a boundary between the curved side surface of the first photo pattern and the curved side surface of the second photo pattern.

12. The method as claimed in claim 11, wherein:
each of the photo patterns has a maximum width at the second surface and a minimum width at the first surface, and
a difference between the maximum width and the minimum width is 3 μm or more.

13. The method as claimed in claim 11, wherein:
the base member includes a metal substrate, and
forming the mask material layer includes plating a metal material on a surface of the base member using a plating method.

14. The method as claimed in claim 11, wherein the mask material layer has a thickness of 1 to 20 μm.

15. The method as claimed in claim 11, wherein:
forming the photoresist pattern includes patterning a photoresist material layer formed on the base member, and
the photoresist material layer includes a negative photoresist material, which contains a binder, a photosensitizer, a solvent, and an additive that captures radicals generated by the photosensitizer in response to irradiation of light.

16. A deposition mask, comprising:
a blocking part including an uneven first surface and an even second surface facing the first surface; and
a plurality of pattern openings surrounded by the blocking part, each of the pattern openings including a first opening and a second opening connected to each other between the first surface and the second surface of the blocking part,
the first opening becoming narrower from the first surface of the blocking part toward the second surface of the blocking part, the first opening having a curved side surface, and the second opening becoming narrower from the first opening toward the second surface of the blocking part, the second opening having a curved side surface extending from the curved side surface of the first opening, and an inflection point being located at a boundary between the curved side surface of the first opening and the curved side surface of the second opening.

17. The deposition mask as claimed in claim 16, wherein:
each of the pattern openings has a maximum width at the first surface of the blocking part and a minimum width at the second surface of the blocking part,
a difference between the maximum width and the minimum width is 3 μm or more, and
the blocking part has a thickness of 1 to 20 μm.

18. The deposition mask as claimed in claim 16, wherein the first surface of the blocking part is a convex surface.

19. The deposition mask as claimed in claim 16, wherein the blocking part contains a metal material or an inorganic material.

20. The deposition mask as claimed in claim 16, wherein a taper angle formed by a virtual plane connecting the curved side surface of the first opening located at the first surface of the blocking part and the curved side surface of the second opening located at the second surface of the blocking part and a virtual plane parallel to the first surface of the blocking part is 45 degrees or less.
